(19) United States
(12) Patent Application Publication
(10) Pub. No.: US 2026/0293223 A1
(43) Pub. Date: Sep. 24, 2026

(54) MANUFACTURING METHOD FOR TRANSISTOR DEVICE

(71) Applicant: INSTITUTE OF MICROELECTRONICS OF THE CHINESE ACADEMY OF SCIENCES, Beijing (CN)

(72) Inventors: Ling LI, Beijing (CN); Ming LIU, Beijing (CN); Di GENG, Beijing (CN); Xinlv DUAN, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,691

(22) PCT Filed: Aug. 24, 2022
(86) PCT No.: PCT/CN2022/114594

§ 371 Date: Dec. 10, 2024

(30) Foreign Application Priority Data
Jun. 10, 2022 (CN) 202210657082.1

(51) Int. Cl. H10D 62/10; H10D 30/01; H10D 30/67; H10W 20/41; H10W 20/42

(52) U.S. Cl. CPC H10D 62/102; H10D 30/0318; H10D 30/6755; H10D 30/6757; H10D 30/6728; H10D 30/6731; H10W 20/422; H10W 20/435

(57) ABSTRACT

Disclosed in the present disclosure is a manufacturing method for a transistor device. The method comprises: providing a substrate; sequentially forming on one side of the substrate a first electrode layer, a first insulating layer and a second electrode layer; forming a via hole that penetrates the first electrode layer and the first insulating layer, wherein the bottom of the via hole extends to the second electrode layer; and sequentially forming on a side face of the via hole a semiconductor layer, a gate insulating layer and a gate electrode. One or more embodiments of the present invention help to manufacture a transistor device having good grid-control capability, and the manufactured device can better realize scaling, which is beneficial to a large-scale array.

### CROSS-REFERENCE TO RELATED PATENT APPLICATIONS

This application claims a priority from the Chinese Patent Application No. 202210657082.1, filed with the Chinese Patent Office on Jun. 10, 2022, entitled “MANUFACTURING METHOD FOR TRANSISTOR DEVICE”, contents of which are incorporated herein by reference in its entirety.

### FIELD OF THE INVENTION

The present disclosure relates to the technical field of semiconductors, and in particular to a method for manufacturing a transistor device.

### BACKGROUND OF THE INVENTION

At present, an integrated circuit is constantly evolving to finer dimensions, with advanced process being one of the top several nodes in integrated circuit fabrication. While the size of a transistor continues to shrink, a planar transistor structure gradually shows defects such as a relatively high leakage current. Therefore, in order to meet better gate control performance and avoid the leakage current, it is a current mainstream development direction to make a three-dimensional structure of a Fin Field Effect Transistor (FinFET). However, it is difficult for the current process to further reduce a channel area on this structure, and it is difficult to further shrink the entire device structure.

Therefore, it is an urgent problem to be solved at present how to manufacture a transistor device with good gate control capability.

### SUMMARY OF THE INVENTION

In view of the above problems, the present disclosure provides a method for manufacturing a transistor device, which is beneficial to manufacture a transistor device with good gate control capability, and the manufactured device can better miniaturized and is beneficial to form a large-scale array.

According to the present disclosure, there is provided a method for manufacturing a transistor device including: providing a substrate; forming in sequence a first electrode layer, a first insulating layer and a second electrode layer on one side of the substrate; forming a via hole penetrating the first electrode layer and the first insulating layer, in which the bottom of the via hole extends to the second electrode layer; and forming in sequence a semiconductor layer, a gate insulating layer and a gate on the side of the via hole.

According to one or more embodiments of the present disclosure, the gate and the channel are fabricated as a vertical structure during the manufacturing process, and a semiconductor layer is fabricated to surround the gate to form a Channel-All-Around (CAA) structure. The area of the semiconductor layer can be effectively increased, the number of carriers in the semiconductor layer is increased, and current conduction efficiency is improved. Meanwhile, since the semiconductor layer fully surrounds an outer side of the gate, the area of the semiconductor layer corresponding to the gate is effectively increased, so that the control capability of the gate on the semiconductor layer is improved.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the following sets forth specific embodiments of the present disclosure.

### BRIEF DESCRIPTION OF THE DRAWINGS

In order to more clearly illustrate the technical solutions in the embodiments of the present disclosure, the accompanying drawings used in the description of the embodiments will be briefly described below. Obviously, the drawings in the following description are some embodiments of the present disclosure, and that other drawings can be derived from these drawings without inventive step for a person of ordinary skill in the art.

FIG. 1 is a flowchart of a method for manufacturing a transistor device according to one or more embodiments of the present disclosure;

FIGS. 1A to 16 are schematic diagrams of transistor device structures formed at different manufacturing stages using a method for manufacturing a transistor device according to one or more embodiments of the present disclosure;

FIGS. 17 and 18 are schematic diagrams of a direction of an electric field formed at a gate terminal according to one or more embodiments of the present disclosure;

FIG. 19 is a schematic diagram of a length of a gate extending into a second electrode layer and an outer diameter of a semiconductor layer according to one or more embodiments of the present disclosure; and

FIG. 20 is a schematic diagram of a structure of a semiconductor layer according to one or more embodiments of the present disclosure.

### DETAILED DESCRIPTION OF THE INVENTION

Embodiments of the present disclosure will be described below with reference to the drawings. Nevertheless, it will be understood that the description is by way of example only and is not intended to limit the scope of the disclosure. Further, in the following description, descriptions of well-known structures and techniques are omitted in order to avoid unnecessarily obscuring the concepts of the present disclosure.

Various structural diagrams according to embodiments of the present disclosure are shown in the drawings. The figures are not to scale, in which certain details have been exaggerated and may have been omitted for clarity of presentation. The shapes of the various regions, layers and the relative sizes, positional relationships between them shown in the figures are merely exemplary, deviations may in practice be due to manufacturing tolerances or technical limitations, and those skilled in the art may additionally design regions/layers with different shapes, sizes, relative positions according to practical needs.

In the context of the present disclosure, when a layer/element is referred to as being “on” another layer/element, it can be directly on that another layer/element, or an intervening layer/element can be present there between. Additionally, if a layer/element is positioned “on” another layer/element in one orientation, the layer/element can be positioned “under” that another layer/element when the orientation is reversed.

Current manufacturing processes for a transistor device include a manufacturing process for a transistor with a planar structure and a manufacturing process for a transistor with a three-dimensional structure. For example, there is a manufacturing process for a fin field effect transistor. However, these manufacturing processes are difficult to further shrink the area of the device and improve gate control performance. In view of the above, according to the embodiment of the present disclosure, there is provided a method for manufacturing a transistor device. In this manufacturing method, a gate and a channel are fabricated as a vertical structure during a manufacturing process, and a semiconductor layer is fabricated to surround the gate to form a Channel-All-Around (CAA) structure. It can effectively increase the area of the semiconductor layer, increase the number of carriers in the semiconductor layer, and improve the current conduction efficiency. Meanwhile, since the semiconductor layer completely surrounds the outside of the gate, the area of the semiconductor layer corresponding to the gate is effectively increased, thereby improving the control capability of the gate to the semiconductor layer. This manufacturing process increases the control area of the gate to the semiconductor layer and the area of the semiconductor layer under a limited volume, and can be used to manufacture a transistor device with relatively small size. The overall concept of the present disclosure is described below through a specific embodiment.

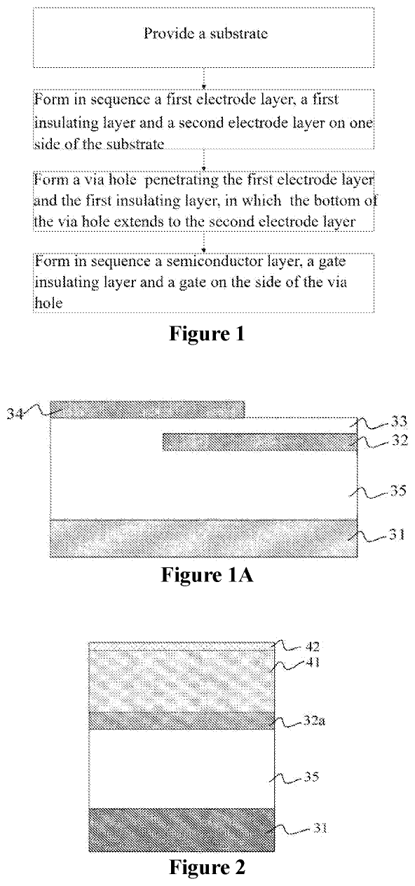

Referring to FIGS. 1 and 1A, a substrate 31 is first provided. The substrate 31 may employ commonly used substrate material such as Si, SiO₂, SiC, etc., even other flexible substrate materials, without limitation. Then, a deposition process can be employed to form in sequence a first electrode layer 32, a first insulating layer 33 and a second electrode layer 34. It can be understood that a second insulating layer 35 may also be formed on one side of the substrate 31 prior to forming the first electrode layer 32, and the first electrode layer 32 is formed on the second insulating layer 35.

An example is given as follows.

An oxide layer with a thickness of 350 nm can be pre-deposited on the silicon substrate as the second insulating layer 35, followed by pre-cleaning, and then a layer of metallic tungsten material (first tungsten material layer 32a) with a thickness of 56 nm is deposited on the oxide layer for manufacturing the first electrode layer 32. Next, a first protective layer 41 and a second protective layer 42 are deposited in sequence. The two protective layers can be SiN and SiO in sequence, and the total thickness can be controlled at 200 nm, as shown in FIG. 2.

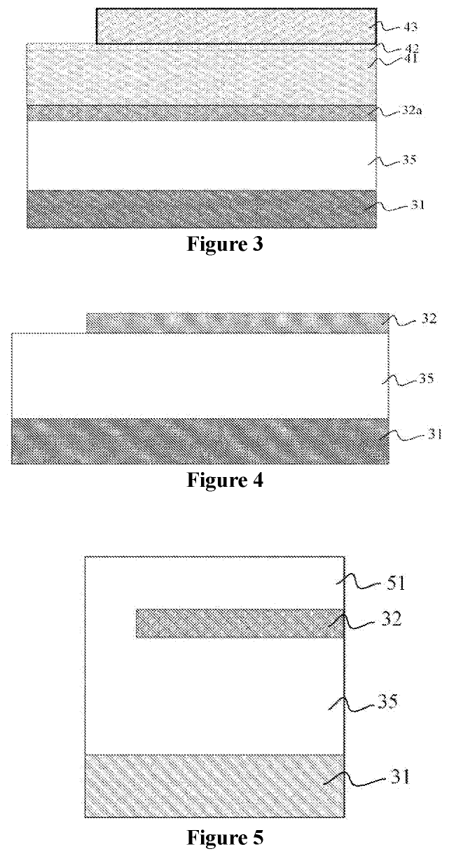

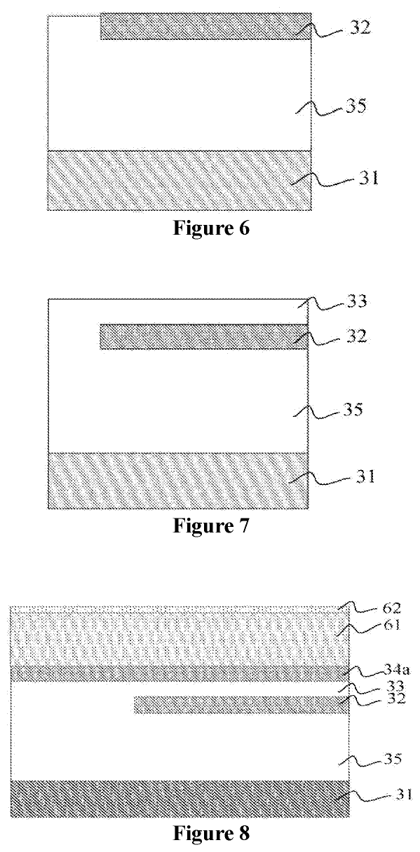

Further, a photoresist 43 is covered on the protective layer, and then lithography development and cleaning are performed, as shown in FIG. 3, so that the first tungsten material layer 32a is fabricated as the first electrode layer 32, as shown in FIG. 4. Next, a first planarization layer 51 is covered on the first electrode layer 32 to fill the patterned first electrode layer 32, as shown in FIG. 5. The thickness of the deposited first planarization layer 51 can be controlled at about 100 nm. Next, chemical mechanical polishing is performed on the first planarization layer until reaching the surface of the first electrode layer 32, followed by cleaning, as shown in FIG. 6.

Further, an oxide layer with a thickness of 50 nm is deposited as the first insulating layer 33, as shown in FIG. 7, to isolate the first electrode layer 32 from the second electrode layer 34.

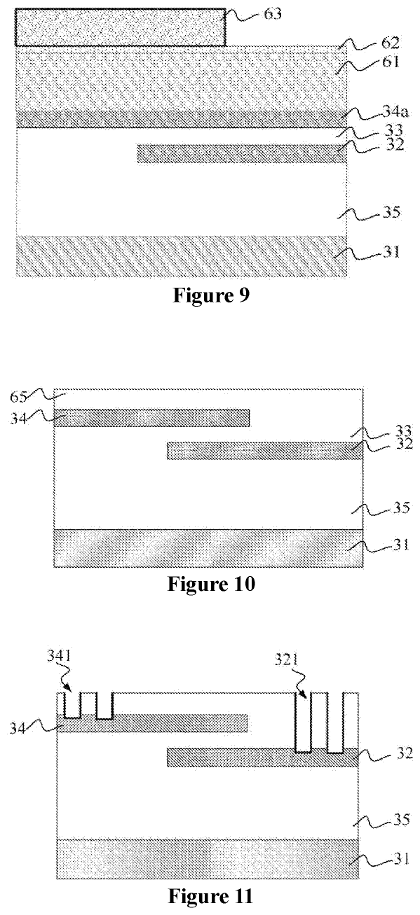

Further, a pre-cleaning is performed and a metal tungsten material with a thickness of 56 nm (a second tungsten material layer 34a) is deposited on the first insulating layer 33 for manufacturing the second electrode layer 34. Next, a first protective layer 61 and a second protective layer 62 are deposited in sequence on the tungsten material layer for manufacturing the second electrode layer 34. Similarly, the two protective layers can be SiN and SiO in sequence, and the total thickness can be controlled at 230 nm. Next, a photoresist 63 is covered on the protective layer, and then lithography development and cleaning are performed, as shown in FIG. 9, so that the second tungsten material layer 34a is fabricated as the second electrode layer 34, as shown in FIG. 1. Next, the second planarization layer 65 is covered on the second electrode layer 34 to fill the patterned second electrode layer 34. The thickness of the deposited planarization layer can be controlled at about 100 nm. Next, chemical mechanical polishing is performed on the second planarization layer 65, followed by cleaning, as shown in FIG. 10.

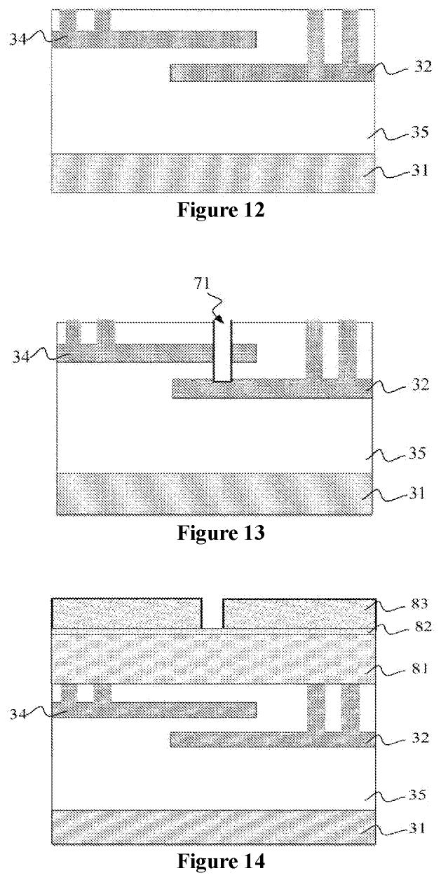

Further, through a patterned mask, the second planarization layer 65 can be etched to form a first wiring hole 321 reaching the first electrode layer 32 and a second wiring hole 341 reaching the second electrode layer 34, as shown in FIG. 11. Next, a metal material is deposited within the first wiring hole 321 and the second wiring hole 341 to lead out the first electrode layer 32 and the second electrode layer 34 for wiring, as shown in FIG. 12. After deposition of the metal material, chemical mechanical polishing is performed.

Next, a via hole 71 penetrating the first electrode layer 32 and the first insulating layer 33 is formed, and the bottom of the via hole 71 extends to the second electrode layer 34, as shown in FIG. 13. Next, referring to FIGS. 13 to 16, a semiconductor layer 72, a gate insulating layer 73, and a gate 74 are formed in sequence on the side of the via hole 71. The semiconductor layer 72 acts as a semiconductor channel.

An example is given as follows.

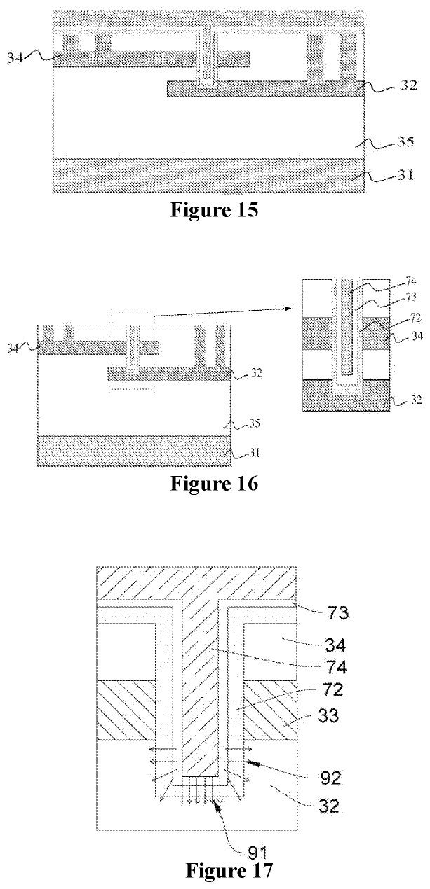

A first protective layer 81 and a second protective layer 82 are deposited in sequence on the second planarization layer 65. Similarly, the two protective layers can be SiN and SiO in sequence, and the total thickness can be controlled at 760 nm, and certainly can also be 200 nm. Next, the photoresist 83 is covered, and the etching position is aligned with the metal overlapping position of the first electrode layer 32 and the second electrode layer 34, as shown in FIG. 14. Etching is performed to form the via hole 71, so that the via hole 71 connects the first electrode layer 32 and the second electrode layer 34, as shown in FIG. 13. Next, referring to FIGS. 15 to 16, a IGZO semiconductor layer with a thickness of 5 nm is deposited within the via hole 71, an AlOₓ gate insulating layer 73 with a thickness of 5 nm is deposited on the surface of the semiconductor layer 72, and finally a gate material such as ITO, IZO or TiN is deposited within the remaining space of the via hole 71 to completely fill the via hole 71, as shown in FIG. 15, or the thickness is controlled at 10 nm. When the gate material finally fills the via hole 71 completely, the diameter of the opening can be controlled in advance to ensure that the final diameter of the gate 74 meets the requirements. In this example, the diameter of the via hole 71 can be controlled to be less than or equal to 50 nm, which can be 40 nm, and the final thickness of the gate 74 can be controlled at 20 nm. Finally, the excess gate material is removed, as shown in FIG. 16.

It should be noted that the gate 74 is made of ITO, IZO, TiN, etc. which can have good conductivity. Additionally, a metal or other highly conductive oxide that is advantageous for growth by an ALD (Atomic Layer Deposition) process may also be used. The first insulating layer 33 can be made of materials such as HfO, HfA1O and Al₂O₃, etc. Of course, the first insulating layer 33 can also be made of a combination of multiple layers of thin films made of different materials. The semiconductor layer 72 can be made of IGZO (Indium Gallium Zinc Oxide), or can be made of IZTO (Indium Zinc Tin Oxide), IGZTO (Indium Gallium Zinc Tin Oxide) or other derivatives with low leakage current and high mobility. The first electrode layer 32 and the second electrode layer 34 can be formed of materials such as TiN, W and Mo. The work function of these materials can be well adapted to the IGZO material, and has good anti-oxidation performance.

When forming the via hole 71, the via hole 71 penetrating the first electrode layer 32, the first insulating layer 33 and the second electrode layer 34 can be controlled to be formed. The via hole 71 extending into the first electrode layer 32 can also be formed, but the via hole 71 does not penetrate the first electrode layer 32, so that the first electrode layer 32 can wrap around the subsequently formed semiconductor layer 72 to achieve good electrical contact.

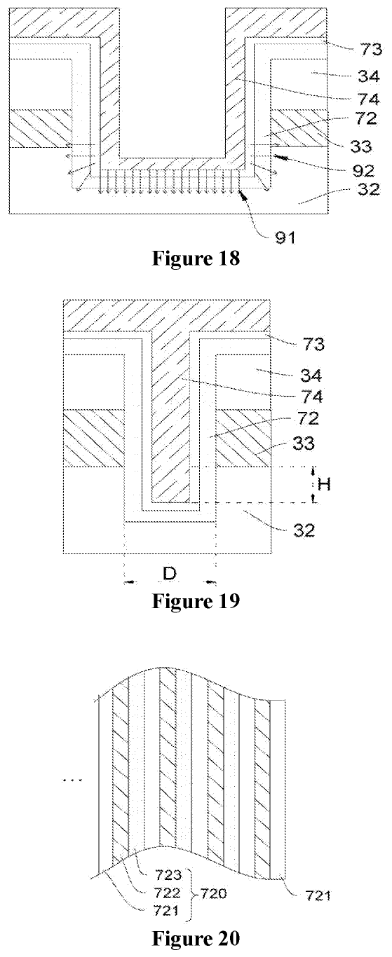

In some embodiments, referring to FIGS. 17 to 18, a length of the formed via hole 71 extending into the first electrode layer 32 is not less than 10 nm. This can ensure that after the gate 74 is formed in the via hole 71, the gate 74 can also extend into the first electrode layer 32. The gate 74 can generate a first electric field 91 parallel to or approximately parallel to the length direction of the gate 74 in the semiconductor layer 72 and the first electrode layer 32 near the bottom of the via hole 71. It can also generate a second electric field 92 perpendicular to or approximately parallel to the length direction of the gate 74 in the semiconductor layer 72 and the first electrode layer 32 near the bottom of the via hole 71. The control capability of the gate 74 on the contact area of the semiconductor layer 72 with the first electrode layer 32 can be further enhanced, thereby improving the performance of the gate 74 of the manufactured device and avoiding the generation of leakage current.

Referring to FIG. 19, when forming the via hole 71, after the gate 74 is deposited in the via hole 71, it can be controlled so that the outer diameter of the formed semiconductor layer 72 extending into the first electrode layer 32 and the length of the gate 74 extending into the first electrode layer 32 satisfy the relationship: H≥0.5×(120 nm−D), where H is the length of the gate 74 extending into the first electrode layer 32, and D is the outer diameter of the semiconductor layer 72 extending into the first electrode layer 32. Further, it is controlled so that D≤100 nm. Therefore, the balance between the first electric field 91 and the second electric field 92 is achieved, it is ensured that the control performance of the gate 74 on the position of the semiconductor layer 72 close to the bottom of the via hole 71 is ensured, and further miniaturization of the device is facilitated. Moreover, during manufacturing, it is also possible to avoid the via hole 71 etching through the first electrode layer 32. At this time, both the end surface and the side of the deposited semiconductor layer 72 can form good contact with the first electrode layer 32, thereby effectively reducing the contact resistance. In addition, when the diameter of the via hole 71 is designed to be larger, contact area between the first electrode layer 32 and the semiconductor layer 72 can be further increased, and contact resistance can be reduced.

When manufacturing the semiconductor layer 72, cyclic deposition can be performed on the side of the via hole 71. An indium oxide thin film layer 721, a gallium oxide thin film layer 722 and a zinc oxide thin film layer 723 are deposited in sequence in each cycle structure 720, as shown in FIG. 20. The deposition sequence of each cycle is the indium oxide thin film layer 721, the gallium oxide thin film layer 722 and the zinc oxide thin film layer 723 sequentially. The semiconductor layer 72 with a high proportion of indium can achieve a relatively large on-state current under the same gate voltage, but the threshold voltage of the device is relatively negative, that is to say, the threshold voltage of the device is less than 0 V and is relatively far from 0 V. The threshold voltage of the device with the semiconductor layer 72 with a low proportion of indium is relatively positive, that is to say, the threshold voltage of the device is greater than 0 V, or is less than 0 V but is relatively close to 0 V, but the on-state current of the device will be relatively small. It should be noted that, depending on different requirements for the expected performance of the device, the criteria for judging whether to be positive or negative may vary. For example, −1 V can be used as a reference, values greater than −1 V are considered positive, and values less than −1 V are considered negative. Therefore, in this embodiment, layered structure design allows accurate control of the ratio of each element in indium, gallium, and zinc in manufacturing process, so as to achieve adjustment and balance of turn-off control ability and mobility of the semiconductor layer 72.

When manufacturing the semiconductor layer 72, the sequence of each cyclic stack can also be the zinc oxide thin film layer 723, the indium oxide thin film layer 721, and the gallium oxide thin film layer 722. Alternatively, it may be the gallium oxide thin film layer 722, the indium oxide thin film layer 721, and the zinc oxide thin film layer 723. Alternatively, it may be the gallium oxide thin film layer 722, the zinc oxide thin film layer 723, and the indium oxide thin film layer 721. Such a stacked structure can ensure that the indium oxide thin film layer 721 and the gallium oxide thin film layer 722 are adjacent to each other, thereby effectively inhibiting the formation of oxygen vacancies and improving the controllability of the fabricated device.

In some embodiments, after the completion of the cyclic stack, the indium oxide thin film layer 721 can further be formed on the surface of the zinc oxide thin film layer 723 to complete all of the fabrication of the semiconductor layer 72. At this time, the gate insulating layer 73 is formed with a surface being the indium oxide thin film layer 721. Therefore, better interface characteristics are obtained, and the sub-threshold characteristic and the working current of the device are improved.

When manufacturing the cyclic stacked film layer, the thickness of each of the indium oxide thin film layer 721, the gallium oxide thin film layer 722, and the zinc oxide thin film layer 723 is controlled to be less than 1 angstrom. In this way, even if different layers of compounds are deposited alternately, the finally formed multi-element semiconductor film cannot be seen as a layered structure, and can still be equivalently considered as a complete mixture of these elements, thus ensuring other properties of the IGZO material.

In some embodiments, the proportion of deposited material for each film can be controlled when manufacturing the cyclic stacked film layer. For example, the proportion of the indium oxide material in each cycle or in the entire semiconductor layer 72 can be controlled to be ⅗ to ¾. The indium oxide material in this proportion can achieve a relatively large on-state current under the same gate voltage condition of the device. Further, the proportion of the gallium oxide material can be set to be the same as that of the zinc oxide material in each cycle or in the entire semiconductor layer 72, so as to ensure that the gate 74 has a good shutdown performance for the semiconductor layer 72 while ensuring that the relatively large open-state current is reached, thereby achieving a balance between high current and easy shutdown of the semiconductor layer 72. That is, the proportion of the material in each cycle or in the entire semiconductor layer 72 can be controlled so that the ratio of InOₓ:GaOₓ:ZnOₓ can be in the range from 3:1:1 to 6:1:1, for example, 5:1:1.

In some embodiments, the thickness of the formed semiconductor layer can be controlled to be 3 nm to 5 nm, thereby ensuring that the semiconductor layer 72 has a better mobility, and at the same time, it is conducive to the further miniaturization of the device, as well as high-density and large-scale array fabrication.

In summary, according to the embodiments of the present disclosure, there is provided a method for manufacturing a transistor device. The gate and the channel are fabricated as a vertical structure during the manufacturing process, and a semiconductor layer is fabricated to surround the gate to form a Channel-All-Around (CAA) structure. The area of the semiconductor layer can be effectively increased, the number of carriers in the semiconductor layer is increased, and the current conduction efficiency is improved. Meanwhile, since the semiconductor layer fully surrounds the outer side of the gate, the area of the semiconductor layer corresponding to the gate is effectively increased, so that the control capability of the gate on the semiconductor layer is improved.

In the above description, technical details such as patterning and etching of each layer are not described in detail. However, it should be understood by those skilled in the art that layers, regions, and the like of a desired shape can be formed by various technical means. In addition, in order to form the same structure, those skilled in the art may also design a method that is not exactly the same as the method described above. In addition, although the embodiments have been described above respectively, this does not mean that the measures in the various embodiments cannot be advantageously used in combination.

Although the preferred embodiments of the present disclosure have been described, those skilled in the art can make additional changes and modifications to these embodiments once they learn the basic inventive concept. Therefore, the appended claims are intended to be interpreted as including the preferred embodiments and all changes and modifications falling within the scope of the present disclosure.

Obviously, those skilled in the art can make various modifications and variations to the present disclosure without departing from the spirit and scope of the present disclosure. In this way, if these modifications and variations of the present disclosure fall within the scope of the claims of the present disclosure and their equivalent technologies, the present disclosure also intends to include these modifications and variations.

1. A method for manufacturing a transistor device comprising:
providing a substrate;
forming in sequence a first electrode layer, a first insulating layer and a second electrode layer on one side of the substrate;
forming a via hole penetrating the first electrode layer and the first insulating layer, wherein the bottom of the via hole extends to the second electrode layer; and
forming in sequence a semiconductor layer, a gate insulating layer and a gate on the side of the via hole.

2. The method according to claim 1, wherein the forming of a via hole penetrating the first electrode layer and the first insulating layer comprises:
forming a via hole penetrating the first electrode layer, the first insulating layer and the second electrode layer.

3. The method according to claim 1, wherein the forming of a via hole penetrating the first electrode layer and the first insulating layer comprises:
forming a via hole penetrating the first electrode layer and the first insulating layer, so that the length of a portion of the via hole extending into the second electrode layer is not less than 10 nm.

4. The method according to claim 1, wherein an outer diameter of the formed semiconductor layer extending into the second electrode layer and a length of a portion of the gate extending into the second electrode layer satisfy a relationship of H≥0.5×(120 nm−D), wherein H is the length of the portion of the gate extending into the second electrode layer, and D is the outer diameter of an end portion of the semiconductor layer extending into the second electrode layer.

5. The method according to claim 1, wherein materials for the semiconductor layer comprises indium oxide, gallium oxide and zinc oxide, and the forming of the semiconductor layer on the side of the via hole comprises:
cyclically forming an indium oxide thin film layer, a gallium oxide thin film layer and a zinc oxide thin film layer on the side of the via hole, wherein the deposition sequence of each cycle is sequentially the indium oxide thin film layer, the gallium oxide thin film layer, and the zinc oxide thin film layer.

6. The method according to claim 5, wherein after cyclically forming an indium oxide thin film layer, a gallium oxide thin film layer and a zinc oxide thin film layer on the side of the via hole, the method further comprises:
forming an indium oxide thin film layer on a surface of the zinc oxide thin film layer, wherein the gate insulating layer is formed with a surface being the indium oxide thin film layer.

7. The method according to claim 1, wherein materials for the semiconductor layer comprises indium oxide, gallium oxide and zinc oxide, and the forming of the semiconductor layer on the side of the via hole comprises:
forming the semiconductor layer with the proportion of the indium oxide being ⅗ to ¾.

8. The method according to claim 1, wherein materials for the semiconductor layer comprises indium oxide, gallium oxide and zinc oxide, and the forming of the semiconductor layer on the side of the via hole comprises:
forming the semiconductor layer with the proportion of the gallium oxide being the same as that of the zinc oxide.

9. The method according to claim 1, wherein before forming in sequence the first electrode layer, the first insulating layer and the second electrode layer on one side of the substrate, the method further comprises:
forming a second insulating layer on the one side of the substrate, wherein the first electrode layer is formed on a surface of the second insulating layer away from the substrate.

10. The method according to claim 1, wherein the forming of the semiconductor layer comprises:
forming the semiconductor layer with a thickness of 3 nm to 5 nm.
